(19) United States
(12) Patent Application Publication
(10) Pub. No.: US 2026/0253556 A1
(43) Pub. Date: Aug. 27, 2026

(54) DISPLAY DEVICE AND ELECTRONIC APPARATUS INCLUDING THE SAME

(71) Applicant: SAMSUNG DISPLAY CO., LTD., YONGIN-SI (KR)

(72) Inventors: KYEUK LEE, Yongin-si (KR); BYUNGSEOK CHOI, Yongin-si (KR); SUNKWANG KIM, Yongin-si (KR); SI HYUN AHN, Yongin-si (KR); HWANYOUNG JANG, Yongin-si (KR)

(21) Appl. No.: 19/401,730

(22) Filed: Nov. 26, 2025

(30) Foreign Application Priority Data
Feb. 24, 2025 (KR) 10-2025-0023432

(51) Int. Cl. G09G 3/3275; H10K 59/121; H10K 59/126; H10K 59/131

(52) U.S. Cl. CPC G09G 3/3275; H10K 59/1213; H10K 59/1216; H10K 59/126; H10K 59/131; G09G 2300/043; G09G 2300/0819; G09G 2330/028

(57) ABSTRACT

A display device includes a plurality of data lines connected to a plurality of pixels, and a plurality of voltage lines connected to the plurality of pixels. The plurality of data lines includes a first data line connected to a first sub-pixel, a second data line connected to a second sub-pixel, and a third data line connected to a third sub-pixel, and the first to third data lines are disposed between the first sub-pixel and the third sub-pixel in a plan view. The plurality of voltage lines is spaced apart from the first data line, the second data line, and the third data line with the first sub-pixel or the third sub-pixel interposed therebetween in the plan view.

### CROSS-REFERENCE TO RELATED APPLICATIONS

This application claims priority under 35 U.S.C. §119 to Korean Patent Application No. 10-2025-0023432, filed on February 24, 2025 in the Korean Intellectual Property Office, the disclosure of which is incorporated by reference in its entirety herein.

### 1. TECHNICAL FIELD

The present disclosure herein relates to a display device and an electronic apparatus including the same, and more particularly, to a display device capable of increasing display quality and an electronic apparatus including same.

### 2. DISCUSSION OF RELATED ART

Among display devices, a light emitting display device is a self emissive display device that displays an image using a light emitting diode (LED) that produces light by recombination of electrons and holes. Such a light emitting display device has the advantage of having a relatively fast response time and at the same time, being driven by a relatively low power consumption.

The display device includes a display panel that displays an image, a gate driver that sequentially supplies scan signals to scan lines provided on the display panel, a data driver that supplies data signals to data lines provided on the display panel, and a voltage generator that supplies voltages to voltage lines provided on the display panel.

### SUMMARY

An aspect of the present disclosure is to provide a display device capable of increasing display quality and an electronic apparatus including the same.

According to an embodiment of the present disclosure a display device includes a display panel comprising a plurality of pixels. Each of the plurality of pixels includes a light emitting element and a pixel circuit connected to the light emitting element. A plurality of data lines is connected to the plurality of pixels. A plurality of voltage lines is connected to the plurality of pixels. A data driver is connected to the plurality of data lines. A voltage generator provides a plurality of voltages to the plurality of voltage lines. The plurality of pixels comprises a first pixel and a second pixel. Each of the first pixel and the second pixel comprises a first sub-pixel, a second sub-pixel, and a third sub-pixel, sequentially arranged in a first direction. The plurality of data lines comprises a first data line connected to the first sub-pixel, a second data line connected to the second sub-pixel, and a third data line connected to the third sub-pixel. The first data line, the second data line, and the third data line are disposed between the first sub-pixel and the third sub-pixel in a plan view. The plurality of voltage lines is spaced apart from the first data line, the second data line, and the third data line with the first sub-pixel or the third sub-pixel interposed therebetween in the plan view.

In an embodiment, the first data line may be disposed between the first sub-pixel and the second sub-pixel in the plan view, and the second data line and the third data line may be disposed between the second sub-pixel and the third sub-pixel in the plan view.

In an embodiment, the third sub-pixel may be symmetrically arranged with respect to the second sub-pixel based on the second data line and the third data line.

In an embodiment, the first and second data lines may be disposed between the first sub-pixel and the second sub-pixel in the plan view, and the third data line may be disposed between the second sub-pixel and the third sub-pixel in the plan view.

In an embodiment, the first sub-pixel may be symmetrically arranged with respect to the second sub-pixel based on the first data line and the second data line.

In an embodiment, the plurality of data lines and the plurality of voltage lines may be disposed on a same layer as each other.

In an embodiment, the display panel may further include a plurality of horizontal voltage lines and a light shielding pattern, the plurality of horizontal voltage lines and the light shielding pattern may be disposed on a same layer as each other, and the plurality of voltage lines may be respectively connected to the plurality of horizontal voltage lines.

In an embodiment, the display panel may further include an insulating pattern partially covering a semiconductor pattern, and disposed under a gate, and a first insulating layer that covers the semiconductor pattern and the gate.

In an embodiment, the plurality of data lines and the plurality of voltage lines may be disposed on the first insulating layer.

In an embodiment, the plurality of voltage lines may include a first driving voltage line, a second driving voltage line, a reference voltage line, and an initialization voltage line, the second driving voltage line, the initialization voltage line, and the reference voltage line may be spaced apart from the first data line with the first sub-pixel interposed therebetween in the plan view, and the first driving voltage line may be spaced apart from the third data line with the third sub-pixel interposed therebetween in the plan view.

In an embodiment, the pixel circuit may include a plurality of transistors, each of the plurality of transistors including a semiconductor pattern and a gate, and each of the plurality of transistors may include a first transistor connected between the first driving voltage line and the light emitting element, a second transistor connected between one of the plurality of data lines and the first transistor, and a third transistor connected to the reference voltage line.

In an embodiment, the semiconductor pattern of the first transistor may be connected to a light shielding pattern overlapping the semiconductor pattern of the first transistor.

In an embodiment, the pixel circuit may further include a first capacitor formed by the light shielding pattern and the gate of the first transistor, and a second capacitor formed by the light shielding pattern and a capacitor electrode, and the capacitor electrode may be disposed on a same layer as the semiconductor pattern of the first transistor.

In an embodiment, the pixel circuit may further include a fourth transistor connected between the initialization voltage line and the light emitting element, a fifth transistor connected between the first driving voltage line and the first transistor, and a sixth transistor connected between the first transistor and the second driving voltage line.

In an embodiment, the reference voltage line may include a first reference voltage line connected to the third transistor, and a second reference voltage line connected to the second capacitor.

In an embodiment, the first pixel and the second pixel may be disposed repeatedly in the first direction, and the first pixel and the second pixel may be disposed alternately in a second direction intersecting the first direction.

In an embodiment, the first driving voltage line and the second driving voltage line may be disposed between the first pixel and the second pixel in the plan view, the first reference voltage line may be adjacent to the first pixel in the plan view, and the second reference voltage line may be disposed between the first pixel and the second pixel in the plan view.

According to an embodiment of the present disclosure, an electronic device includes a display device. A processor controls operation of the display device. The display device comprises a display panel comprising a plurality of pixels. Each of the plurality of pixels comprises a light emitting element and a pixel circuit connected to the light emitting element. A plurality of data lines is connected to the plurality of pixels. A plurality of voltage lines is connected to the plurality of pixels. A data driver is connected to the plurality of data lines. A voltage generator provides a plurality of voltages to the plurality of voltage lines. The plurality of pixels comprises a first pixel and a second pixel. Each of the first pixel and the second pixel comprises a first sub-pixel, a second sub-pixel, and a third sub-pixel, sequentially arranged in a first direction. The plurality of data lines comprises a first data line connected to the first sub-pixel, a second data line connected to the second sub-pixel, and a third data line connected to the third sub-pixel. The first data line, the second data line, and the third data line are disposed between the first sub-pixel and the third sub-pixel in a plan view. The plurality of voltage lines is spaced apart from the first data line, the second data line, and the third data line with the first sub-pixel or the third sub-pixel interposed therebetween in the plan view.

In an embodiment, the first data line may be disposed between the first sub-pixel and the second sub-pixel in the plan view, the second data line and the third data line may be disposed between the second sub-pixel and the third sub-pixel in the plan view, and the third sub-pixel may be symmetrically arranged with respect to the second sub-pixel based on the second data line and the third data line.

In an embodiment, the plurality of data lines and the plurality of voltage lines may be disposed on a same layer as each other.

### BRIEF DESCRIPTION OF THE DRAWINGS

The accompanying drawings are included to provide a further understanding of the present inventive concept and are incorporated in and constitute a part of this specification. The drawings illustrate non-limiting embodiments of the present inventive concept and, together with the description, serve to explain principles of the present inventive concept. In the drawings:

FIG. 1 is a perspective view of a display device according to an embodiment of the present inventive concept;

FIG. 2A is an exploded perspective view of a display device according to an embodiment of the present inventive concept;

FIG. 2B is a cross-sectional view of a display device according to an embodiment of the present inventive concept;

FIG. 3 is a block diagram of a display device according to an embodiment of the present inventive concept;

FIG. 4A is an equivalent circuit diagram of a pixel according to an embodiment of the present inventive concept;

FIG. 4B is a waveform diagram of driving signals for driving the pixel illustrated in FIG. 4A according to an embodiment of the present inventive concept;

FIG. 5 is a cross-sectional view of a display panel according to an embodiment of the present inventive concept;

FIG. 6A is a plan view of multiple conductive patterns according to an embodiment of the present inventive concept;

FIG. 6B is a plan view of semiconductor patterns and gates according to an embodiment of the present inventive concept;

FIG. 6C is a plan view of voltage lines and data lines according to an embodiment of the present inventive concept;

FIG. 7 is a plan of sub-pixels according to an embodiment of the present inventive concept;

FIG. 8 is a plan view of a plurality of pixels according to an embodiment of the present inventive concept;

FIG. 9 is a block diagram of an electronic apparatus according to an embodiment of the present inventive concept; and

FIG. 10 illustrates schematic diagrams of electronic apparatuses according to various embodiments of the present inventive concept.

### DETAILED DESCRIPTION OF EMBODIMENTS

In the description, when an element (or a region, a layer, a part, or the like) is referred to as being "on," "connected with" or "combined with" another element, it can be directly disposed on/connected with/bonded to the other element, or intervening third elements may also be disposed. When an element is referred to as being "directly on," "directly connected with" or "directly combined with" another element, no intervening elements may be present.

Like reference numerals refer to like elements throughout. In the drawings, the thicknesses, ratios, and dimensions of elements may be exaggerated for effective explanation of technical contents. "and/or" may include one or more combinations that may define relevant elements.

It will be understood that, although the terms first, second, or the like may be used herein to describe various elements, these elements should not be limited by the terms. The terms are only used to distinguish one element from another element. For example, a first element could be termed a second element without departing from the scope of the present inventive concept. Similarly, a second element could be termed a first element. As used herein, the singular forms are intended to include the plural forms as well, unless the context clearly indicates otherwise.

In addition, the terms "below", "beneath", "on" and "above" are used for explaining the relation of elements shown in the drawings. The terms are relative concepts and are explained based on the direction shown in the drawing.

It will be further understood that the terms "comprises" or "comprising," when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which the present inventive concept belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

Hereinafter, non-limiting embodiments of the present inventive concept will be described with reference to the drawings.

The present disclosure concerns a display device that includes data lines disposed between sub-pixels in a plan view and voltage lines disposed outside of the sub-pixels in a plan view. The sub-pixels are interposed between the data lines and the voltages lines in a plan view so that the data lines are not directly adjacent to the voltage lines. Therefore, electrical coupling between the data lines and the voltage lines is reduced and the display device may provide increased display quality.

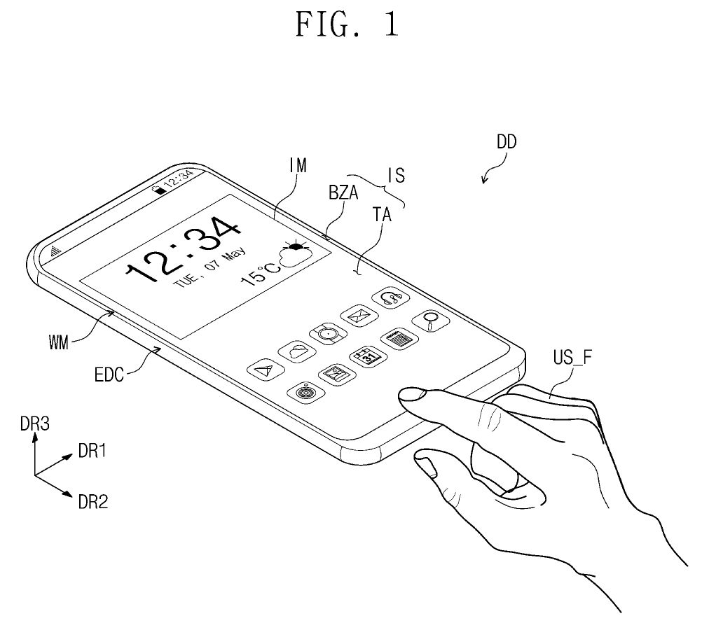

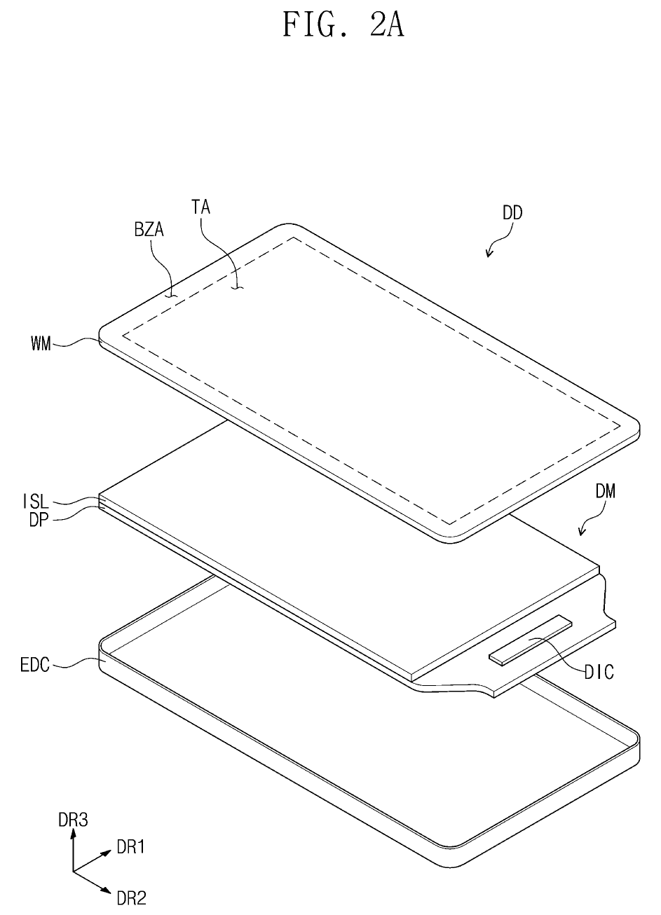

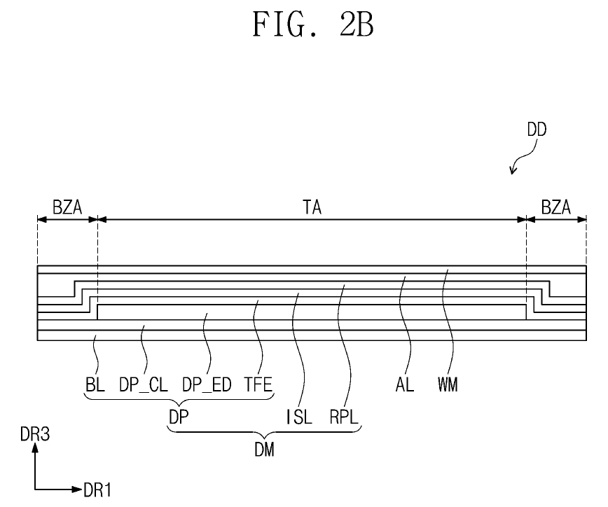

FIG. 1 is a perspective view of a display device according to an embodiment of the present inventive concept. FIG. 2A is an exploded perspective view of a display device according to an embodiment of the present inventive concept. FIG. 2B is a cross-sectional view of a display device according to an embodiment of the present inventive concept.

Referring to FIG. 1 and FIG. 2A, a display device DD according to an embodiment of the present inventive concept may have a rectangular shape (e.g., in a plan view) having short sides parallel to a first direction DR1 and long sides parallel to a second direction DR2 intersecting the first direction DR1. However, embodiment of the present inventive concept are not necessarily limited thereto, and the display device DD may have various shapes such as a circle and a polygon (e.g., in a plan view).

The display device DD may be a device activated according to an electrical signal. The display device DD may include various embodiments. For example, the display device DD may be applied to electronic apparatuses such as a smart watch, a tablet, a laptop, a computer, and a smart television. However, embodiments of the present inventive concept are not necessarily limited thereto and the display device DD may be applied to various different small-sized, medium-sized and large-sized electronic devices.

Hereinafter, a normal direction substantially perpendicular to a plane defined by the first direction DR1 and the second direction DR2 is defined as a third direction DR3. In this specification, the meaning of "if viewed on a plane" or “in a plan view” may mean a state viewed from the third direction DR3. While embodiments show the first to third directions DR1 to DR3 being perpendicular to each other, embodiments of the present disclosure are not necessarily limited thereto and the first to third directions DR1 to DR3 may intersect each other at various different angles.

The top surface of the display device DD may be defined as a display surface IS, and may be parallel to a plane defined by the first direction DR1 and the second direction DR2. Images IM generated in the display device DD may be provided to a user through the display surface IS.

The display surface IS may be divided into a transparent area TA and a bezel area BZA. The transparent area TA may be an area where images IM are displayed. The user views the images IM through the transparent area TA. In this embodiment, the transparent area TA is illustrated as a rectangular shape with rounded corners (e.g., in a plan view). However, embodiments of the present inventive concept are not necessarily limited thereto, and the transparent area TA may have various shapes (e.g., in a plan view) and is not necessarily limited to any one embodiment.

The bezel area BZA is adjacent to the transparent area TA. The bezel area BZA may have a predetermined color. The bezel area BZA may surround the transparent area TA (e.g., in a plan view). Accordingly, the shape of the transparent area TA may be substantially defined by the bezel area BZA. However, embodiments of the present inventive concept are not necessarily limited thereto and the bezel area BZA may be adjacent to only one side of the transparent area TA or may be omitted.

The display device DD may detect an external input applied from the outside (e.g., the external environment). The external input may include various types of inputs provided from the outside of the display device DD. For example, the external input may include contact by a part of the body such as the user's hand US_F or contact by a separate device (e.g., an active pen or a digitizer), as well as external input (e.g., hovering) applied in proximity to the display device DD or at a predetermined distance. In addition, the external input may have various forms such as force, pressure, temperature and light.

The display device DD may include a window WM, a display module DM, and a housing EDC. In this embodiment, the window WM and the housing EDC are combined to form the appearance of the display device DD.

The front surface of the window WM defines the display surface IS of the display device DD. The window WM may include an optically transparent insulating material. For example, the window WM may include glass or plastic. The window WM may have a multilayer structure or a single layer structure. For example, in an embodiment the window WM may include a plurality of plastic films bonded with an adhesive, or may include a glass substrate and a plastic film bonded with an adhesive.

The display module DM may include a display panel DP and an input sensing layer ISL. The display panel DP displays an image according to an electrical signal, and the input sensing layer ISL may detect an external input applied from the outside. The external input may be provided in various forms.

The display panel DP according to an embodiment of the present inventive concept may be a light emitting display panel, and is not necessarily limited thereto. For example, the display panel DP may be an organic light emitting display panel, an inorganic light emitting display panel, or a quantum dot light emitting display panel. The emission layer of the organic light emitting display panel may include an organic light emitting material, and the emission layer of the inorganic light emitting display panel may include an inorganic light emitting material. The emission layer of the quantum dot light emitting display panel may include quantum dots, quantum rods, or the like. Hereinafter, the display panel DP is described as an organic light emitting display panel for economy of explanation.

Referring to FIG. 2B, in an embodiment the display panel DP includes a base layer BL, a circuit layer DP_CL, an element layer DP_ED, and an encapsulation layer TFE. The display panel DP according to the present inventive concept may be a flexible display panel. However, embodiment of the present inventive concept are not necessarily limited thereto. For example, the display panel DP may be a foldable display panel that is folded based on a folding axis or a rigid display panel.

The base layer BL may include a synthetic resin layer. In an embodiment, the synthetic resin layer may be a polyimide-based resin layer. However, the material of the base layer BL is not necessarily limited thereto. In addition, the base layer BL may include a glass substrate, a metal substrate, or an organic/inorganic composite material substrate.

The circuit layer DP_CL is disposed on the base layer BL (e.g., disposed directly thereon in the third direction DR3). The circuit layer DP_CL is disposed between the base layer BL and the element layer DP_ED (e.g., in the third direction DR3). The circuit layer DP_CL includes at least one insulating layer and a circuit element. Hereinafter, the insulating layer included in the circuit layer DP_CL is referred to as an intermediate insulating layer. The intermediate insulating layer includes at least one intermediate inorganic film and at least one intermediate organic film. The circuit element may include a pixel driving circuit included in each of a plurality of pixels for displaying an image, and a sensor driving circuit included in each of a plurality of sensors for recognizing external information. In an embodiment, the external information may be biometric information. For example, in an embodiment the sensor may be a fingerprint recognition sensor, a proximity sensor, an iris recognition sensor, a blood pressure measurement sensor, or an illuminance sensor. In addition, the sensor may be an optical sensor that optically recognizes biometric information. The circuit layer DP_CL may further include signal lines connected to the pixel driving circuit and/or the sensor driving circuit.

The element layer DP_ED may include a light emitting element included in each of the pixels and a light receiving element included in each of the sensors. In an embodiment of the present inventive concept, the light receiving element may be a photodiode. The light receiving element may be a sensor that detects light reflected by a user's fingerprint or reacts to light.

The encapsulation layer TFE seals the element layer DP_ED. The encapsulation layer TFE may include at least one organic film and at least one inorganic film. The inorganic film includes an inorganic material and may protect the element layer DP_ED from moisture/oxygen. In an embodiment, the inorganic film may include, but is not necessarily limited to, a silicon nitride layer, a silicon oxy nitride layer, a silicon oxide layer, a titanium oxide layer, or an aluminum oxide layer. The organic layer may include an organic material and protect the element layer DP_ED from foreign substances such as dust particles and contaminants.

An input sensing layer ISL may be formed on the display panel DP (e.g., in the third direction DR3). The input sensing layer ISL may be directly disposed on the encapsulation layer TFE. According to an embodiment of the present inventive concept, the input sensing layer ISL may be formed on the display panel DP by a continuous process. For example, if the input sensing layer ISL is directly disposed on the display panel DP, an adhesive film is not disposed between the input sensing layer ISL and the encapsulation layer TFE (e.g., in the third direction DR3). Alternatively, in an embodiment an adhesive film may be disposed between the input sensing layer ISL and the display panel DP. In this embodiment, the input sensing layer ISL is not manufactured through a continuous process with the display panel DP, but may be manufactured through a separate process from the display panel DP and then subsequently fixed to the top surface of the display panel DP by an adhesive film.

The input sensing layer ISL may detect an external input (e.g., a user's touch) and change the external input into a predetermined input signal, and provide the input signal to the display panel DP. The input sensing layer ISL may include a plurality of sensing electrodes for detecting an external input. The sensing electrodes may detect an external input in a capacitive manner. The display panel DP may receive an input signal from the input sensing layer ISL and generate an image corresponding to the input signal.

The display module DM may further include an anti-reflection layer RPL. The anti-reflection layer RPL may reduce the reflectivity of external light incident from above the display device DD towards the display panel DP. The external light may not be recognized by the user due to the anti-reflection layer RPL. In an embodiment of the present inventive concept, the anti-reflection layer RPL may be disposed on the input sensing layer ISL (e.g., disposed directly thereon in the third direction DR3). However, embodiments of the present inventive concept are not necessarily limited thereto. In some embodiments, the anti-reflection layer RPL may be disposed between the display panel DP and the input sensing layer ISL (e.g., in the third direction DR3). The anti-reflection layer RPL may include a plurality of color filters respectively disposed corresponding to pixels. The color filters may filter external light to the same color as the pixels. In this embodiment, the external light may not be visible to the user. However, embodiments of the present inventive concept are not necessarily limited thereto, and the anti-reflection layer RPL may include a phase retarder and/or a polarizer to reduce the reflectivity of the external light.

The display device DD according to an embodiment of the present inventive concept may further include an adhesive layer AL. In an embodiment, the window WM may be attached to the anti-reflection layer RPL by the adhesive layer AL. In an embodiment, the adhesive layer AL may include an optical clear adhesive, an optically clear adhesive resin, or a pressure sensitive adhesive (PSA).

Referring again to FIG. 2A, the display module DM may further include a driving chip DIC. In an embodiment of the present inventive concept, the driving chip DIC may be mounted on the display panel DP adjacent to one end of the display panel DP. Alternatively, the driving chip DIC may be mounted on a flexible circuit film coupled to one side of the display panel DP.

The housing EDC is coupled with the window WM. The housing EDC is coupled with the window WM to provide a predetermined internal space. The display module DM may be accommodated in the internal space. The housing EDC may include a material having relatively high rigidity. For example, in an embodiment the housing EDC may include a plurality of frames and/or plates including glass, plastic, or metal, or composed of a combination thereof. The housing EDC may stably protect the elements of the display device DD accommodated in the internal space from external impact. In an embodiment, a battery module or the like that supplies power required for the overall operation of the display device DD may be disposed between the display module DM and the housing EDC.

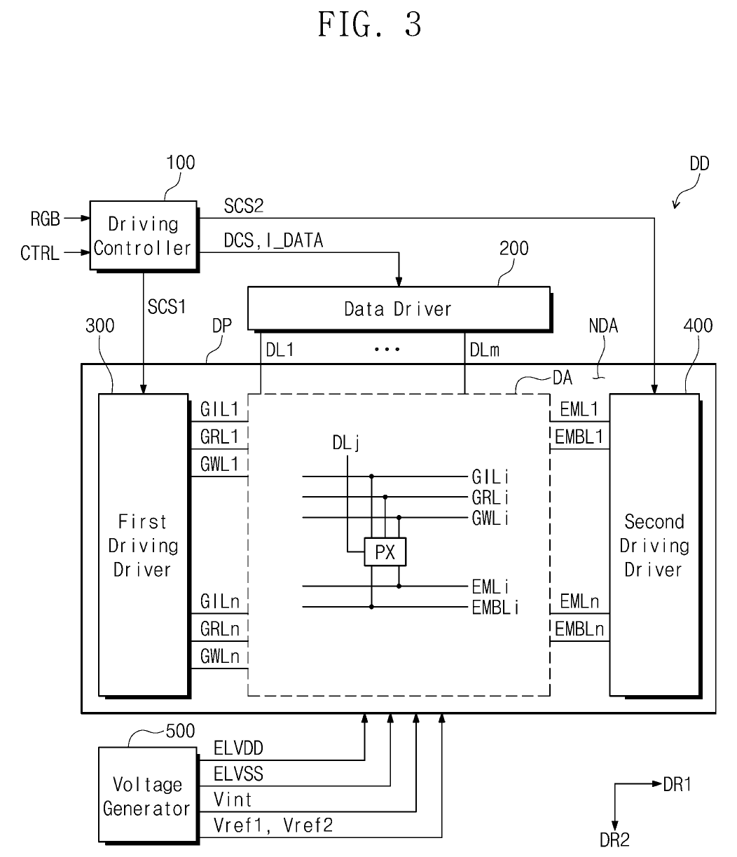

FIG. 3 is a block diagram of a display device according to an embodiment of the present inventive concept.

Referring to FIG. 3, the display device DD includes a display panel DP, a panel driver, and a driving controller 100. In an embodiment of the present inventive concept, the panel driver includes a data driver 200, a first driving driver 300, a second driving driver 400, and a voltage generator 500.

The driving controller 100 receives an image signal RGB and a control signal CTRL. The driving controller 100 generates image data I_DATA obtained by converting the data format of the image signal RGB to match the interface specification with the data driver 200. In an embodiment, the driving controller 100 outputs a first control signal SCS1, a second control signal SCS2, and a third control signal DCS.

The data driver 200 receives the third control signal DCS and the image data I_DATA from the driving controller 100. The data driver 200 converts the image data I_DATA into data signals and outputs the data signals to a plurality of data lines DL1 to DLm described below. In an embodiment, the data signals are analog voltages corresponding to the grayscale values of the image data I_DATA. In an embodiment of the present inventive concept, the data driver 200 may be embedded in the driving chip DIC illustrated in FIG. 2A.

The first driving driver 300 receives the first control signal SCS1 from the driving controller 100, and the second driving driver 400 receives the second control signal SCS2 from the driving controller 100. The first driving driver 300 and the second driving driver 400 may output scan signals as the scan lines in response to the first control signal SCS1 and the second control signal SCS2, respectively.

The voltage generator 500 generates voltages necessary for the operation of the display panel DP. In this embodiment, the voltage generator 500 generates a first driving voltage ELVDD, a second driving voltage ELVSS, an initialization voltage Vint, a first reference voltage Vref1, and a second reference voltage Vref2.

The display panel DP may include a display area DA corresponding to (e.g., at least partially overlapping in the third direction DR3) a transparent area TA (shown in FIG. 1) and a non-display area NDA corresponding to a bezel area BZA (shown in FIG. 1).

The display panel DP may include a plurality of pixels PX disposed in the display area DA. In an embodiment, the display panel DP further includes initialization scan lines GIL1 to GILn, reset scan lines GRL1 to GRLn, write scan lines GWL1 to GWLn, first emission control lines EML1 to EMLn, second emission control lines EMBL1 to EMBLn, and data lines DL1 to DLm. The initialization scan lines GIL1 to GILn, the reset scan lines GRL1 to GRLn, the write scan lines GWL1 to GWLn, the first emission control lines EML1 to EMLn, and the second emission control lines EMBL1 to EMBLn extend in the first direction DR1 and are spaced apart from each other in the second direction DR2. The data lines DL1 to DLm extend in the second direction DR2 and are spaced apart from each other in the first direction DR1. Here, n and m are natural numbers greater than or equal to 1.

The plurality of pixels PX are electrically connected to the initialization scan lines GIL1 to GILn, the reset scan lines GR1 to GRLn, the write scan lines GWL1 to GWLn, the first emission control lines EML1 to EMLn, the second emission control lines EMBL1 to EMBLn, and the data lines DL1 to DLm, respectively. For example, in an embodiment each of the plurality of pixels PX may be electrically connected to three scan lines. However, the number of scan lines connected to each pixel PX is not necessarily limited thereto and may vary. FIG. 3 illustrates a pixel PX connected to an ith initialization scan line GILi (hereinafter, an initialization scan line) among the initialization scan lines GIL1 to GILn, an ith reset scan line GRLi (hereinafter, a reset scan line) among the reset scan lines GR1 to GRLn, an ith write scan line GWLi (hereinafter, a write scan line) among the write scan lines GWL1 to GWLn, an ith first emission control line EMLi (hereinafter, a first emission control line) among the first emission control lines EML1 to EMLn, an ith second emission control line EMBLi (hereinafter, a second emission control line) among the second emission control lines EMBL1 to EMBLn, and a jth data line DLj (hereinafter, a data line) among the data lines DL1 to DLm.

The first driving driver 300 and the second driving driver 400 may be disposed in the non-display area NDA of the display panel DP. In an embodiment, the first driving driver 300 may output initialization scan signals to the initialization scan lines GIL1 to GILn, reset scan signals to the reset scan lines GRL1 to GRLn, and write scan signals to the write scan lines GWL1 to GWLn in response to the first control signal SCS1. In an embodiment, the second driving driver 400 may output first emission control signals to the first emission control lines EML1 to EMLn, and second emission control signals to the second emission control lines EMLB1 to EMLBn in response to the second control signal SCS2.

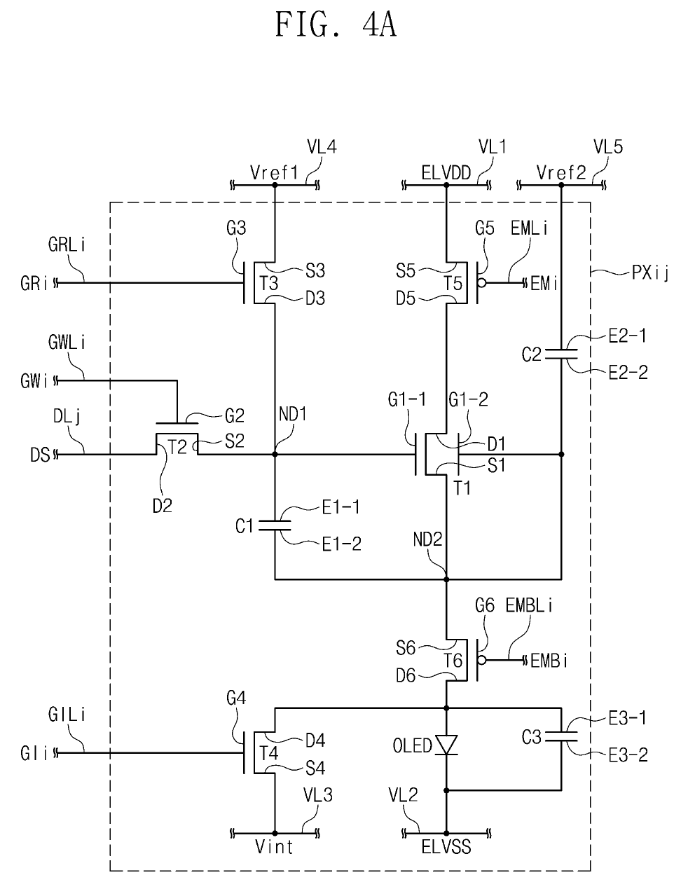

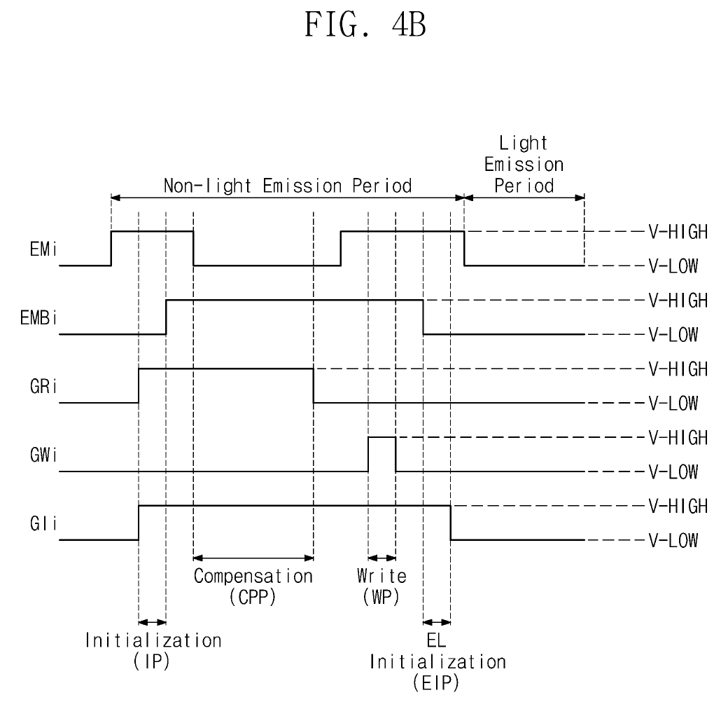

FIG. 4A is an equivalent circuit diagram of a pixel according to an embodiment of the present inventive concept. FIG. 4B is a waveform diagram of driving signals for driving the pixel illustrated in FIG. 4A.

FIG. 4A illustrates an equivalent circuit diagram of one pixel PXij among the plurality of pixels PX shown in FIG. 3. Since each of the plurality of pixels PX has the same circuit structure, a detailed description of the remaining pixels will be omitted in the description of the circuit structure of the pixel PXij.

In this embodiment, a pixel circuit may include first to sixth transistors T1 to T6, first to third capacitor C1 to C3, and a light emitting element OLED. In this embodiment, the first to fourth transistors T1 to T4 are described as N-type, and the fifth and sixth transistors T5 and T6 are described as P-type. In this embodiment of the present inventive concept, the third capacitor C3 may be omitted. However, embodiments of the present inventive concept are not necessarily limited thereto and the number of transistors, the type of transistors and the arrangement thereof may vary.

In this embodiment, the first transistor T1 includes two gates, and each of the second to sixth transistors T2 to T6 includes one gate, but is not necessarily limited thereto. At least one of the second to sixth transistors T2 to T6 may include two gates.

In this embodiment, the first transistor T1 may be a driving transistor, and the second transistor T2 may be a switching transistor. A node to which the gate G1-1 (hereinafter, a first gate or an upper gate) of the first transistor T1 is connected may be defined as a first node ND1, and a node to which the source S1 of the first transistor T1 is connected may be defined as a second node ND2.

The first transistor T1 is electrically connected between a first voltage line VL1 (which may be referred to as a first driving voltage line) that receives a first driving voltage ELVDD and the second node ND2. The first transistor T1 may include a source S1 (hereinafter, a first source) connected to the second node ND2, a drain D1 (hereinafter, a first drain), a channel region (or a semiconductor region), and a first gate G1-1. The first transistor T1 may further include a gate G1-2 (hereinafter, a lower gate) connected to the second node ND2. The first transistor T1 controls the driving current of a light emitting element OLED based on a charge capacity of a first capacitor C1.

The second transistor T2 is electrically connected between a data line DLj and the first node ND1. The second transistor T2 may include a source S2 (hereinafter, a second source) connected to the first node ND1, a drain D2 (hereinafter, a second drain) connected to the data line DLj, a channel region, and a gate G2 (hereinafter, a second gate) connected to a write scan line GWLi. The second transistor T2 outputs a data voltage. The first capacitor C1 receives the data voltage.

The third transistor T3 is electrically connected between the first node ND1 and a fourth voltage line VL4 (which may be referred to as the first reference voltage line) that receives a first reference voltage Vref1. The third transistor T3 may include a drain D3 (hereinafter, a third drain) connected to the first node ND1, a source S3 (hereinafter, a third source) connected to the fourth voltage line VL4, a channel region, and a third gate G3 connected to the reset scan line GRLi.

The fourth transistor T4 is electrically connected between a third voltage line VL3 (which may be referred to as an initialization voltage line) that receives the initialization voltage Vint and the light emitting element OLED. The fourth transistor T4 may include a drain D4 (hereinafter, a fourth drain) connected to the first electrode of the light emitting element OLED, a source S4 (hereinafter, a fourth source) connected to a third voltage line VL3, a channel region, and a fourth gate G4 connected to the initialization scan line GILi.

The fifth transistor T5 is electrically connected between the first voltage line VL1 and the first drain D1 of the first transistor T1. In this embodiment, the fifth transistor T5 may include a source S5 (hereinafter, a fifth source) connected to the first voltage line VL1, a drain D5 (hereinafter, a fifth drain) connected to the first drain D1 of the first transistor T1, a channel region, and a fifth gate G5 connected to the first emission control line EMLi.

The sixth transistor T6 is electrically connected between the second node ND2 and the first electrode of the light emitting element OLED. In this embodiment, the sixth transistor T6 may include a source S6 (hereinafter, a sixth source) connected to the second node ND2, a drain D6 (hereinafter, a sixth drain) connected to the first electrode of the light emitting element OLED, a channel region, and a sixth gate G6 connected to the second emission control line EMBLi.

The light emitting element OLED is electrically connected between the sixth drain D6 and a second voltage line VL2 (which may be referred to as a second driving voltage line) that receives a second driving voltage ELVSS. The light emitting element OLED includes a first electrode connected to the sixth drain D6 and a second electrode connected to the second voltage line VL2.

The first capacitor C1 is electrically connected between the first node ND1 and the second node ND2. The first capacitor C1 includes a first electrode E1-1 connected to the first node ND1 and a second electrode E1-2 connected to the second node ND2.

The second capacitor C2 is electrically connected between a fifth voltage line VL5 (which may be referred to as a second reference voltage line) receiving a second reference voltage Vref2 and the second node ND2. The second capacitor C2 includes a first electrode E2-1 connected to the fifth voltage line VL5 and a second electrode E2-2 connected to the second node ND2.

The third capacitor C3 is electrically connected between the first electrode and the second electrode of the light emitting element OLED. The third capacitor C3 includes a first electrode E3-1 connected to the first electrode of the light emitting element OLED and a second electrode E3-2 connected to the second electrode of the light emitting element OLED.

The operation of the pixel PXij will be described in more detail with reference to FIGS. 4A and 4B. The display device DD (see FIG. 3) displays an image for each frame period. In an embodiment, each of the initialization scan lines, the reset scan lines, the write scan lines, the first emission control lines, and the second emission control lines is sequentially scanned during the frame period. FIG. 4B illustrates a portion of the frame period, and illustrates a timing diagram of a first emission control signal EMi output from the first emission control line EMLi, a second emission control signal EMBi output from the second emission control line EMBLi, a reset scan signal GRi output from the reset scan line GRLi, a write scan signal GWi output from the write scan line GWLi, and an initialization scan signal GIi output from the initialization scan line GILi.

Referring to FIG. 4B, each of the signals EMi, EMBi, GRi, GWi, and GIi may have a high level V-HIGH during some periods and a low level V-LOW during some periods. In an embodiment, the first to fourth transistors of N-type T1 to T4 described above are turned on when the corresponding control signal has a high level V-HIGH, and the fifth and sixth transistors of P-type T5 and T6 are turned on when the corresponding control signal has a low level V-LOW.

In an embodiment, during an initialization period IP, since the reset scan signal GRi and the initialization scan signal GIi have a high level V-HIGH, the third transistor T3 and the fourth transistor T4 are turned on, and since the second emission control signal EMBi has a low level V-LOW, the sixth transistor T6 is turned on. The third transistor T3 is turned on so that the first node ND1 is initialized to the first reference voltage Vref1, and the fourth transistor T4 is turned on so that the first electrode of the light emitting element OLED may be initialized to the initialization voltage Vint. The sixth transistor T6 is turned on so that the second node ND2 may be initialized to the initialization voltage Vint. The first capacitor C1 may be initialized to the difference value between the first reference voltage Vref1 and the initialization voltage Vint. The second capacitor C2 may be initialized to the difference value between the second reference voltage Vref2 and the initialization voltage Vint. The third capacitor C3 may be initialized to the difference value between the second driving voltage ELVSS and the initialization voltage Vint. In an embodiment of the present inventive concept, the second reference voltage Vref2 may be the first driving voltage ELVDD.

In an embodiment, during a compensation period CPP, since the reset scan signal GRi has a high level V-HIGH, the third transistor T3 is turned on, and since the first emission control signal EMi has a low level V-LOW, the fifth transistor T5 is turned on. A voltage corresponding to the threshold voltage of the first transistor T1 is compensated for in the first capacitor C1.

In an embodiment, during a write period WP, since the write scan signal GWi has a high level V-HIGH, the second transistor T2 is turned on. The second transistor T2 outputs a voltage (e.g., a data voltage) corresponding to the data signal DS. As a result, the first capacitor C1 is charged with a voltage level corresponding to the data signal DS. For example, the first capacitor C1 is charged with the data signal DS of which threshold voltage of the first transistor T1 is compensated for. The threshold voltages of the driving transistors may be different for each of the plurality of pixels PX (see FIG. 3), but the pixel PXij shown in FIG. 4A may supply a current proportional to the data signal DS to the light emitting element OLED regardless of the deviation in the threshold voltages of the driving transistors.

In an embodiment, during an EL initialization period EIP, since the initialization scan signal GIi has a high level V-HIGH, the fourth transistor T4 is turned on, and since the second emission control signal EMBi has a low level V-LOW, the sixth transistor T6 is turned on. The first electrode and the second node ND2 of the light emitting element OLED may be initialized to the initialization voltage Vint.

In an embodiment, thereafter during the light emission period, since the first light emission control signal EMi and the second light emission control signal EMBi have a low level V-LOW, the fifth transistor T5 and the sixth transistor T6 are turned on. The first transistor T1 provides a current corresponding to the charge capacity stored in the first capacitor C1 to the light emitting element OLED. The light emitting element OLED may emit light with a brightness corresponding to the data signal DS.

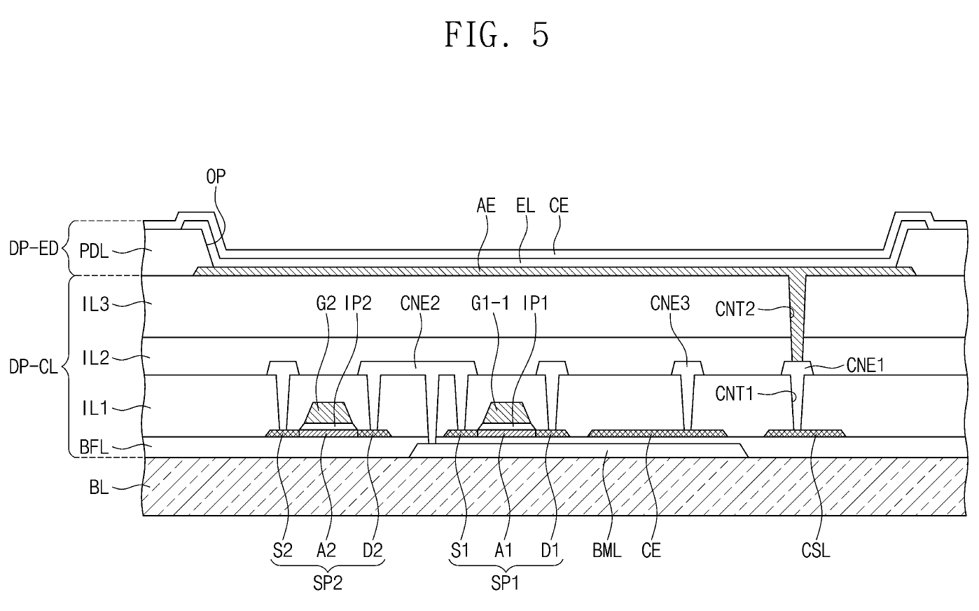

FIG. 5 is a cross-sectional view of a display panel according to an embodiment of the present inventive concept.

Referring to FIGS. 4A and 5, in an embodiment a display panel DP may include a base layer BL, a circuit layer DP_CL, and an element layer DP_ED.

In an embodiment, the base layer BL may include a synthetic resin layer. The synthetic resin layer may include a thermosetting resin. In an embodiment, the synthetic resin layer may be a polyimide-based resin layer. However, embodiments of the present inventive concept are not necessarily limited thereto and the material of the base layer BL may vary. In an embodiment, the synthetic resin layer may include at least one of an acrylic resin, a methacrylic resin, a polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, or an organic/inorganic composite material substrate.

A buffer layer BFL including at least one inorganic layer is disposed on the upper surface of the base layer BL (e.g., disposed directly thereon in the third direction DR3). In an embodiment, the buffer layer BFL may include at least one of aluminum oxide, titanium oxide, silicon oxide, silicon nitride, silicon oxynitride, zirconium oxide, or hafnium oxide. The inorganic layer may be formed as a multilayer. The buffer layer BFL may prevent foreign substances from entering from the outside (e.g., the external environment). The buffer layer BFL increases the bonding strength between the base layer BL and a semiconductor pattern and/or conductive pattern disposed on the upper side.

A plurality of conductive patterns may be disposed on the upper surface of the base layer BL (e.g., disposed directly thereon in the third direction DR3). In FIG. 5, a light shielding pattern BML is illustrated as an embodiment among the plurality of conductive patterns. In an embodiment of the present inventive concept, the light shielding pattern BML may correspond to the lower gate G1-2 and the second electrode E2-2 of the second capacitor C2. In an embodiment, the light shielding pattern BML may define a capacitor electrode CE disposed on the upper side and the second capacitor C2.

Semiconductor patterns SP1 and SP2, a capacitor electrode CE, and a connection signal line CSL may be disposed on the buffer layer BFL (e.g., disposed directly thereon in the third direction DR3). In an embodiment, the semiconductor patterns SP1 and SP2 may include polysilicon. However, embodiments of the present inventive concept are not necessarily limited thereto, and the semiconductor patterns SP1 and SP2 may also include amorphous silicon in some embodiments.

In FIG. 5, only the first semiconductor pattern SP1 and the second semiconductor pattern SP2 are shown for economy of explanation. However, semiconductor patterns SP1 and SP2 may be further disposed in other areas of the pixel PXij. The electrical properties of the semiconductor patterns SP1 and SP2 differ depending on whether they are doped or not doped. The semiconductor patterns SP1 and SP2 may include a doped region and a non-doped region. The doped region may be doped with an N-type dopant or a P-type dopant. A P-type transistor includes a doped region doped with a P-type dopant, and an N-type transistor includes a doped region doped with an N-type dopant.

The doped region has a greater conductivity than the non-doped region and substantially functions as an electrode or a signal line. The non-doped region substantially corresponds to the active (e.g., channel) of the transistor. For example, a part of the semiconductor pattern may be the active of the transistor, another part may be the source or drain of the transistor, and another part may be the connecting signal line (e.g., the connecting electrode).

The first source S1, the first drain D1, and the channel region described with reference to FIG. 4A may be formed from the first semiconductor pattern SP1. The first source S1, the first drain D1, and the channel region shown in FIG. 4A may correspond to the first source S1, the first drain D1, and the first channel region A1 in FIG. 5. The first source S1 and the first drain D1 may extend in opposite directions from the first channel region A1 (e.g., in a plan view). In this embodiment, the first drain D1 may be defined as a first input region, and the first source S1 may be defined as a first output region. The first transistor of an N-type T1 is described in an embodiment, but if the first transistor T1 has a P-type property, the definition may be in the opposite way.

The second source S2, the second drain D2, and the channel region described with reference to FIG. 4A may be formed from the second semiconductor pattern SP2. The second source S2, the second drain D2, and the channel region shown in FIG. 4A may correspond to the second source S2, the second drain D2, and the second channel region A2 in FIG. 5. The second source S2 and the second drain D2 may extend in opposite directions from the second channel region A2 (e.g., in a plan view). In this embodiment, the second drain D2 may be defined as a second input region, and the second source S2 may be defined as a first output region. The second transistor T2 of an N type has been described as an embodiment, but if the property of the second transistor T2 is P type, the definition may be in the opposite way.

The capacitor electrode CE may be disposed to partially overlap with the lower light shielding pattern BML (e.g., in the third direction DR3). In an embodiment of the present inventive concept, the capacitor electrode CE may correspond to the first electrode E2-1 of the second capacitor C2. The capacitor electrode CE may define the second capacitor C2 together with the lower light shielding pattern BML.

Insulating patterns IP1 and IP2 may be disposed on the semiconductor patterns SP1 and SP2. In an embodiment, the insulating patterns IP1 and IP2 may include silicon dioxide (SiO₂), silicon nitride (Si₃N₄), aluminum oxide (Al₂O₃), and titanium dioxide (TiO₂). The insulating patterns IP1 and IP2 may partially cover the upper surface of the semiconductor patterns SP1 and SP2. For example, the first insulating pattern IP1 may be disposed to cover the first channel region A1 of the first semiconductor pattern SP1, and the second insulating pattern IP2 may be disposed to cover the second channel region A2 of the second semiconductor pattern SP2.

A first gate G1-1 and a second gate G2 may be disposed on the insulating patterns IP1 and IP2 (e.g., disposed directly thereon in the third direction DR3). The first gate G1-1 may correspond to the first gate G1-1 of the first transistor T1 described with reference to FIG. 4A, and the second gate G2 may correspond to the second gate G2 of the second transistor T2 described with reference to FIG. 4A. In an embodiment, the first gate G1-1 and the second gate G2 may include polysilicon, titanium nitride (TiN), tungsten (W), molybdenum (Mo), and aluminum (Al). Each of the first gate G1-1 and the second gate G2 may overlap the first channel region A1 and the second channel region A2 (e.g., in the third direction DR3).

In an embodiment, the first insulating layer IL1 may be disposed to commonly overlap a plurality of pixels PX (see FIG. 3) and cover the semiconductor patterns SP1 and SP2 and the gates G1-1 and G2. The first insulating layer IL1 may be an inorganic layer and/or an organic layer, and may have a single layer or multilayer structure. In an embodiment, the first insulating layer IL1 may include at least one of aluminum oxide, titanium oxide, silicon oxide, silicon oxynitride, zirconium oxide, or hafnium oxide. In this embodiment, the first insulating layer IL1 may be a silicon oxide layer having a single layer.

Connection electrodes CNE1, CNE2 and CNE3 may be disposed on the first insulating layer IL1 (e.g., disposed directly thereon in the third direction DR3). In an embodiment, the first connection electrode CNE1 may be connected to (e.g., electrically connected thereto) a connection signal line CSL through a first contact hole CNT1 penetrating the first insulating layer IL1, and may be connected to (e.g., electrically connected thereto) an anode electrode AE through a second contact hole CNT2 penetrating the second insulating layer IL2 and the third insulating layer IL3. In an embodiment, the second connection electrode CNE2 may connect (e.g., electrically connect) the first source S1 and the light shielding pattern BML to each other. The third connection electrode CNE3 may connect (e.g., electrically connect) the capacitor electrode CE and the fifth voltage line VL5 to each other.

A second insulating layer IL2 may be disposed on the first insulating layer IL1 (e.g., disposed directly thereon in the third direction DR3). The second insulating layer IL2 may cover the connection electrodes CNE1, CNE2 and CNE3. In this embodiment, the second insulating layer IL2 may be an organic layer and may have a single layer structure, but embodiments of the present inventive concept are not necessarily limited thereto.

A third insulating layer IL3 may be disposed on the second insulating layer IL2 (e.g., disposed directly thereon in the third direction DR3). In this embodiment, the third insulating layer IL3 may be an organic layer and may have a single layer structure. However, embodiments of the present disclosure are not necessarily limited thereto.

An element layer DP_ED is disposed on a circuit layer DP_CL (e.g., disposed directly thereon in the third direction DR3). The element layer DP_ED may include an anode electrode AE. In an embodiment, the anode electrode AE may be connected to (e.g., electrically connected thereto) the first connection electrode CNE1 through a second contact hole CNT2 penetrating the second insulating layer IL2 the third insulating layer IL3.

The element layer DP_ED further includes a pixel defining layer PDL disposed on the circuit layer DP_CL. The pixel defining layer PDL may include an opening part OP defined corresponding to a light emitting element OLED. The opening part OP exposes at least a portion of the anode electrode AE, such as a central portion of the anode electrode AE (e.g., in a plan view).

An emission layer EL is disposed corresponding to the opening part OP defined in the pixel defining layer PDL. In this embodiment, a patterned emission layer EL is illustrated as an embodiment, but embodiments of the present inventive concept are not necessarily limited thereto. Alternatively, in an embodiment a common emission layer may be commonly disposed on a plurality of pixels PX (see FIG. 3). In this case, the common emission layer may produce white light or blue light. A cathode electrode CE is disposed on the emission layer EL (e.g., in the third direction DR3). The cathode electrode CE is commonly disposed on a plurality of pixels PX (see FIG. 3).

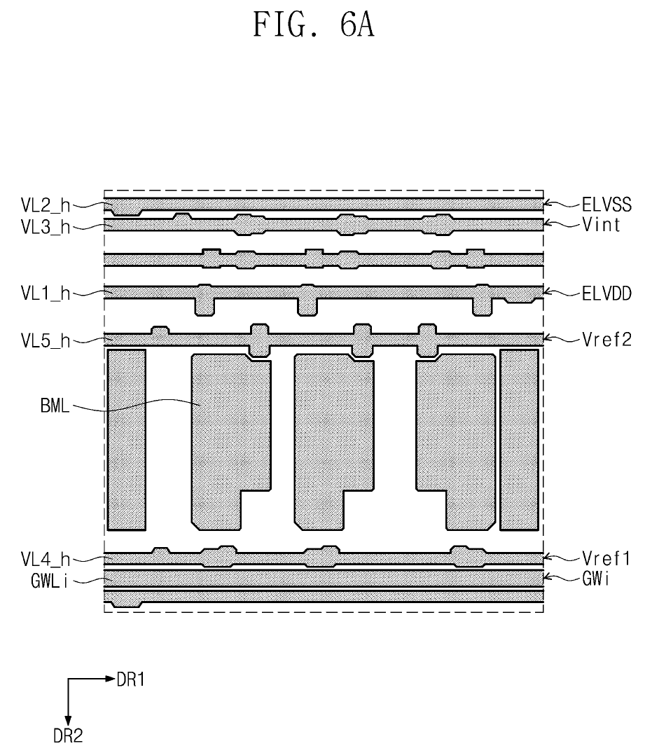

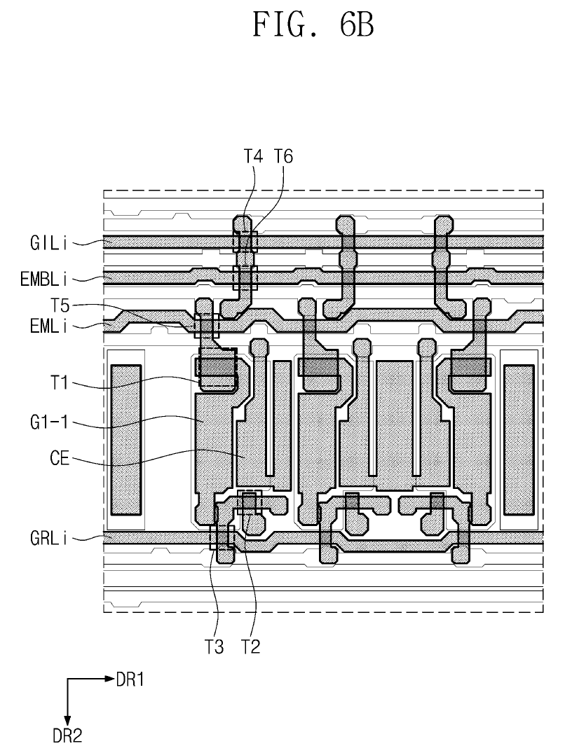

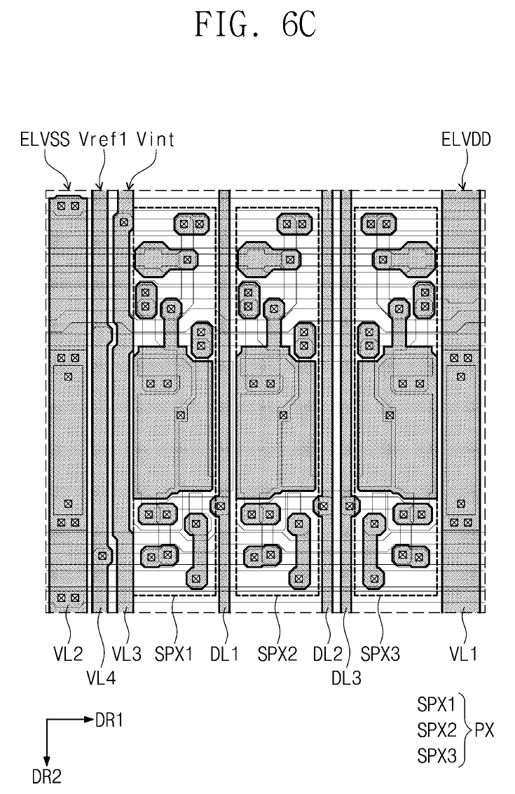

FIG. 6A is a plan view of a plurality of conductive patterns according to an embodiment of the present inventive concept. FIG. 6B is a plan view of semiconductor patterns and gates according to an embodiment of the present inventive concept. FIG. 6C is a plan view of voltage lines and data lines according to an embodiment of the present inventive concept.

Referring to FIGS. 5 and 6A, a plurality of conductive patterns may be simultaneously formed on a base layer BL. In an embodiment, the plurality of conductive patterns may include a first horizontal voltage line VL1_h outputting a first driving voltage ELVDD, a second horizontal voltage line VL2_h outputting a second driving voltage ELVSS, a third horizontal voltage line VL3_h outputting an initialization voltage Vint, a fourth horizontal voltage line VL4_h outputting a first reference voltage Vref1, a fifth horizontal voltage line VL5_h outputting a second reference voltage Vref2, and a light shielding pattern BML. In an embodiment, the first to fifth horizontal voltage lines VL1_h to VL5_h may extend in the first direction DR1 and may be spaced apart from each other in the second direction DR2, respectively. However, embodiments of the present inventive concept are not necessarily limited to the arrangement of the conductive patterns along the second direction DR2 as shown in FIG. 6A and may vary.

The first to fifth horizontal voltage lines VL1_h-VL5_h may be directly connected to a pixel PX (see FIG. 6C) to provide voltages to the pixel PX (see FIG. 6C).

Referring to FIG. 5, FIG. 6A, and FIG. 6B, a plurality of semiconductor patterns and a plurality of gates may be disposed on the plurality of conductive patterns described with reference to FIG. 6A (e.g., disposed directly thereon in the third direction DR3). In an embodiment, the plurality of semiconductor patterns may be formed simultaneously, and the plurality of gates may be formed simultaneously. In FIG. 5, only two semiconductor patterns SP1 and SP2 defining the first transistor T1 and the second transistor T2 and gates G1-1 and G2 are illustrated, but in FIG. 6B, a plurality of semiconductor patterns and a plurality of gates defining the first to sixth transistors T1-T6 are illustrated.

The gates may be a part of the initialization scan line GILi, the reset scan line GRLi, the first emission control line EMLi, and the second emission control line EMBLi. In an embodiment, the initialization scan line GILi, the reset scan line GRLi, the first emission control line EMLi, and the second emission control line EMBLi may extend in the first direction DR1 and may be spaced apart from each other in the second direction DR2. However, embodiments of the present inventive concept are not necessarily limited to the arrangement of the initialization scan line GILi, the reset scan line GRLi, the first emission control line EMLi, and the second emission control line EMBLi along the second direction DR2 as shown in FIG. 6B and may vary.

The first gate G1-1 of the first transistor T1 may overlap with the light shielding pattern BML (e.g., in the third direction DR3) to define the first capacitor C1. The capacitor electrode CE may overlap with the shielding pattern BML to define the second capacitor C2.

The third gate G3 of the third transistor T3 may be a part of the reset scan line GRLi, and the fourth gate G4 of the fourth transistor T4 may be a part of the initialization scan line GILi. The fifth gate G5 of the fifth transistor T5 may be a part of the first emission control line EMLi, and the sixth gate G6 of the sixth transistor T6 may be a part of the second emission control line EMBLi.

Referring to FIGS. 5 and 6C, the first to third data lines DL1 to DL3 and the first to fourth voltage lines VL1 to VL4 may be disposed on the plurality of semiconductor patterns and the plurality of gates described with reference to FIG. 6B. The first to third data lines DL1 to DL3 and the first to fourth voltage lines VL1 to VL4 may be disposed on the same layer as each other. For example, the first to third data lines DL1 to DL3 and the first to fourth voltage lines VL1 to VL4 may be disposed on the first insulating layer IL1 (e.g., directly thereon in the third direction DR3).

In an embodiment, the pixel PX may include a first sub-pixel SPX1, a second sub-pixel SPX2, and a third sub-pixel SPX3. However, embodiments of the present inventive concept are not necessarily limited thereto and the number of sub-pixels included in each pixel PX may vary. Each of the first to third sub-pixels SPX1 to SPX3 may have a configuration similar to that of the pixel PXij described with reference to FIG. 4A. In an embodiment, the first to third sub-pixels SPX1 to SPX3 may be disposed in order along the first direction DR1. In an embodiment of the present inventive concept, the elements (e.g., components) of the first sub-pixel SPX1 and the second sub-pixel SPX2 may be disposed to have an identical arrangement with each other (e.g., in a plan view), but the elements of the third sub-pixel SPX3 may be symmetrically arranged (e.g., in a plan view) with respect to the elements of the first sub-pixel SPX1 or the second sub-pixel SPX2 based on the second data line DL2 and/or the third data line DL3.

In an embodiment, the first to third data lines DL1 to DL3 may extend in the second direction DR2 and may be spaced apart from each other in the first direction DR1. The first to third data lines DL1 to DL3 may be disposed between the first to third sub-pixels SPX1 to SPX3 in a plan view (e.g., in the first direction DR1). For example, each of the first to third data lines DL1 to DL3 may be disposed between adjacent sub-pixels of the first to third sub-pixels SPX1 to SPX3 (e.g., in the first direction DR1) and may each be disposed between an inner edge of the first sub-pixel SPX1 and an inner edge of the third sub-pixel SPX3. In an embodiment, the first data line DL1 may be connected to the first sub-pixel SPX1, the second data line DL2 may be connected to the second sub-pixel SPX2, and the third data line DL3 may be connected to the third sub-pixel SPX3. In an embodiment of the present inventive concept, each of the first to third data lines DL1 to DL3 may be connected to the second transistor T2 of the first to third sub-pixels SPX1 to SPX3.

The first to third data lines DL1 to DL3 may be disposed between the first sub-pixel SPX1 and the third sub-pixel SPX3 (e.g., in a plan view). For example, in an embodiment of the present inventive concept, the first data line DL1 may be disposed between the first sub-pixel SPX1 and the second sub-pixel SPX2 in a plan view (e.g., in the first direction DR1), and the second data line DL2 may be disposed between the second sub-pixel SPX2 and the third sub-pixel SPX3 in a plan view (e.g., in the first direction DR1). Since the elements of the third sub-pixel SPX3 are symmetrically arranged with respect to the first sub-pixel SPX1 or the second sub-pixel SPX2 based on the second data line DL2 and/or the third data line DL3, the third data line DL3 may also be disposed between the second sub-pixel SPX2 and the third sub-pixel SPX3 in a plan view (e.g., in the first direction DR1). Accordingly, the first data line DL1 may be spaced apart from the second data line DL2 and the second sub-pixel SPX2, but the second data line DL2 may be adjacent to the third data line DL3 (e.g., immediately adjacent thereto in a direction opposite to the first direction DR1).

The first to fourth voltage lines VL1 to VL4 may extend in the second direction DR2 and may be spaced apart from each other in the first direction DR1. In an embodiment of the present inventive concept, the second voltage line VL2, the third voltage line VL3, and the fourth voltage line VL4 may be spaced apart from the first data line DL1 with the first sub-pixel SPX1 interposed therebetween in a plan view (e.g., in the first direction DR1), and the first voltage line VL1 may be spaced apart from the third data line DL3 in a plan view with the third sub-pixel SPX3 interposed therebetween (e.g., in the first direction DR1). For example, the first to third data lines DL1 to DL3 may be disposed between the first and third sub-pixels SPX1 and SPX3 in a plan view, but the first to fourth voltage lines VL1 to VL4 may not be disposed between the first and third sub-pixels SPX1 and SPX3, but may be disposed outside the first and third sub-pixels SPX1 and SPX3 (e.g., in a plan view). For example, in an embodiment the second to fourth voltage lines VL2 to VL4 may be disposed outside the first sub-pixel SPX1 in a direction opposite to the first direction DR1 and the first voltage line VL1 may be disposed outside the third sub-pixel SPX3 in the first direction DR1.

In an embodiment, the first voltage line VL1 may be connected to (e.g., electrically connected thereto) the pixel PX through a first horizontal voltage line VL1_h (FIG. 6A) and may provide a first driving voltage ELVDD to the pixel PX. The second voltage line VL2 may be connected to (e.g., electrically connected thereto) the pixel PX through a second horizontal voltage line VL2_h (FIG. 6A) and may provide a second driving voltage ELVSS to the pixel PX. The third voltage line VL3 may be connected to (e.g., electrically connected thereto) the pixel PX through a third horizontal voltage line VL3_h (FIG. 6A) and may provide an initialization voltage Vint to the pixel PX. The fourth voltage line VL4 may be connected to (e.g., electrically connected thereto) the pixel PX through a fourth horizontal voltage line VL4_h and may provide a first reference voltage Vref1 to the pixel PX.

According to an embodiment of the present inventive concept, the first to third data lines DL1 to DL3 are disposed between the first and third sub-pixels SPX1 and SPX3 in a plan view (e.g., in the first direction DR1), but the first to fourth voltage lines VL1 to VL4 may be disposed outside the first and third sub-pixels SPX1 and SPX3 a plan view. For example, the first to third data lines DL1 to DL3 may not be directly adjacent to the first to fourth voltage lines VL1 to VL4. Accordingly, a display device DD (see FIG. 1) with increased display quality may be provided by reducing coupling (e.g., electrical coupling) between the first to third data lines DL1 to DL3 and the first to fourth voltage lines VL1 to VL4.

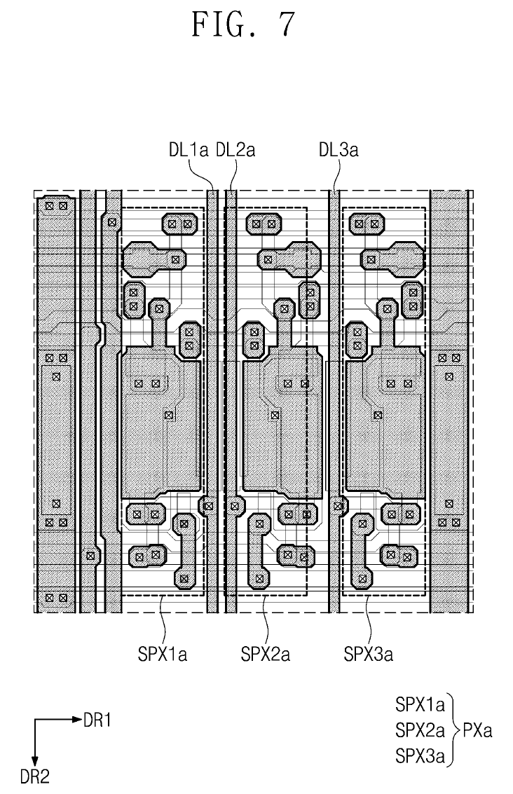

FIG. 7 is a plan view of sub-pixels according to an embodiment of the present inventive concept.

Referring to FIG. 7, a pixel PXa may include a first sub-pixel SPX1a, a second sub-pixel SPX2a, and a third sub-pixel SPX3a. Each of the first to third sub-pixels SPX1a to SPX3a may have a configuration similar to that of the pixel PXij described with reference to FIG. 4A. The first to third sub-pixels SPX1a to SPX3a may be disposed sequentially in the first direction DR1. In an embodiment of the present inventive concept, the elements of the second sub-pixel SPX2a and the third sub-pixel SPX3a may be disposed to have an identical arrangement to each other, but the elements of the first sub-pixel SPX1a may be symmetrically arranged with respect to the elements of the second sub-pixel SPX2a or the third sub-pixel SPX3a based on the first data line DL1a and/or the second data line DL2a.

The first to third data lines DL1a to DL3a may be disposed between the first sub-pixel SPX1a and the third sub-pixel SPX3a in a plan view (e.g., in the first direction DR1). In an embodiment of the present inventive concept, since the elements of the first sub-pixel SPX1a is symmetrically arranged with respect to the elements of the second sub-pixel SPX2a or the third sub-pixel SPX3a based on the first data line DL1a and/or the second data line DL2a, the first data line DL1a may be disposed between the first sub-pixel SPX1a and the second sub-pixel SPX2a in a plan view (e.g., in the first direction DR1). The second data line DL2a may be disposed between the first sub-pixel SPX1a and the second sub-pixel SPX2a in a plan view (e.g., in the first direction DR1), and the third data line DL3a may be disposed between the second sub-pixel SPX2a and the third sub-pixel SPX3a in a plan view (e.g., in the first direction DR1). Accordingly, the second data line DL2a is spaced apart from the third data line DL3a with the second sub-pixel SPX2a therebetween in a plan view (e.g., in the first direction DR1), but the first data line DL1a may be adjacent to the second data line DL2a (e.g., directly adjacent thereto in the first direction DR1).

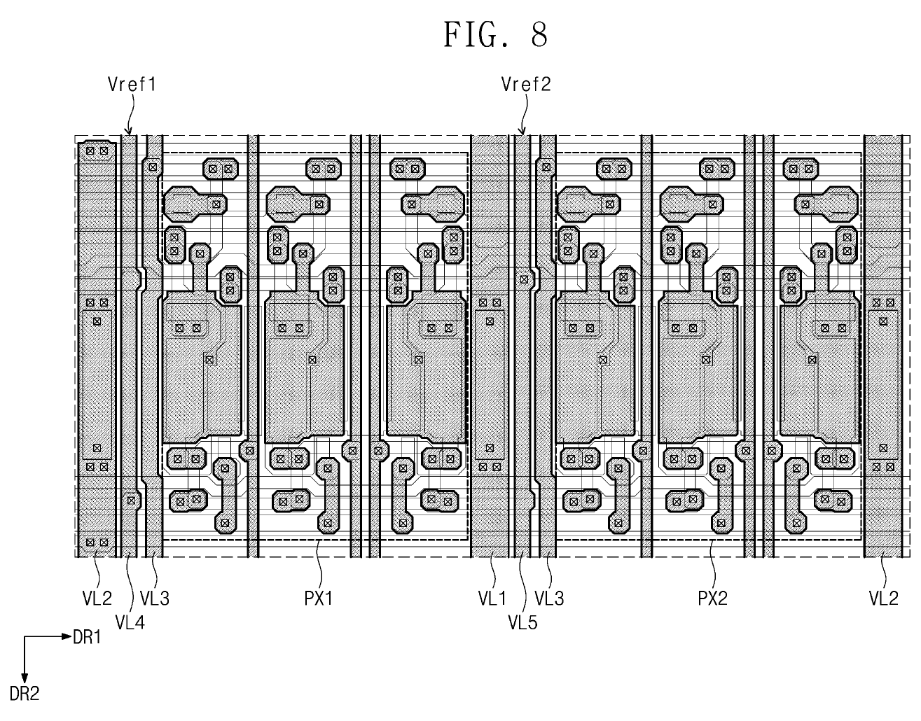

FIG. 8 is a plan view of a plurality of pixels according to an embodiment of the present inventive concept.

Referring to FIG. 8, in an embodiment each of the first pixel PX1 and the second pixel PX2 may be repeatedly disposed in the second direction DR2, and the first pixel PX1 and the second pixel PX2 may be alternately disposed in the first direction DR1. The configuration of each of the first pixel PX1 and the second pixel PX2 is the same as the configuration of the pixel PX described with reference to FIG. 6C.

The first pixel PX1 and the second pixel PX2 may be connected to (e.g., electrically connected thereto) the first to fifth voltage lines VL1 to VL5. The first voltage line VL1 and the second voltage line VL2 may be alternately disposed between the first pixel PX1 and the second pixel PX2 (e.g., in the first direction DR1).

One of the first voltage line VL1 or the second voltage line VL2 may be disposed between the first pixel PX1 and the second pixel PX2 in a plan view (e.g., in the first direction DR1), and the other one may be adjacent to the second pixel PX2 in a plan view (e.g., in the first direction DR1). For example, in an embodiment the first voltage line VL1 may be disposed between the first pixel PX1 and the second pixel PX2 in a plan view (e.g., in the first direction DR1), and the second voltage line VL2 may be positioned closer to the second pixel PX2 among the two pixels PX1 and PX2. For example, the second voltage line VL2 may be disposed outside the second pixel PX2 (e.g., in the first direction DR1). In an embodiment, one of the fourth voltage line VL4 that outputs the first reference voltage Vref1 or the fifth voltage line VL5 that outputs the second reference voltage Vref2 may be positioned closer to the first pixel PX1, and the other one may be disposed between the first pixel PX1 and the second pixel PX2 in a plan view (e.g., in the first direction DR1). For example, in an embodiment of the present inventive concept, the fourth voltage line VL4 may be closer to the first pixel PX1 among the two pixels PX1 and PX2, and the fifth voltage line VL5 may be closer to the second pixel PX2 among the two pixels PX1 and PX2. For example, in an embodiment the fourth voltage line VL4 may be disposed outside the first pixel (e.g., in a direction opposite to the first direction DR1) and the fifth voltage line VL5 may be disposed outside the second pixel PX2 (e.g., in a direction opposite to the first direction DR1). In an embodiment, the fifth voltage line VL5 may be formed simultaneously with the first to fourth voltage lines VL1 to VL4 described with reference to FIG. 6C and disposed on the same layer.

However, the arrangement relationship of the first to fifth voltage lines VL1 to VL5 is not necessarily limited thereto, and the present inventive concept includes various configurations in which the first to fifth voltage lines VL1 to VL5 are disposed between the first pixel PX1 and the second pixel PX2 (e.g., in a plan view), which are alternately arranged, so as not to be adjacent to the first to third data lines DL1 to DL3 in a plan view(see FIG. 6C).

The display device according to an embodiment may be applied to various electronic devices (“apparatuses”). An electronic apparatus according to an embodiment includes the display device described above, and may further include a module or device having additional functions in addition to the display device.

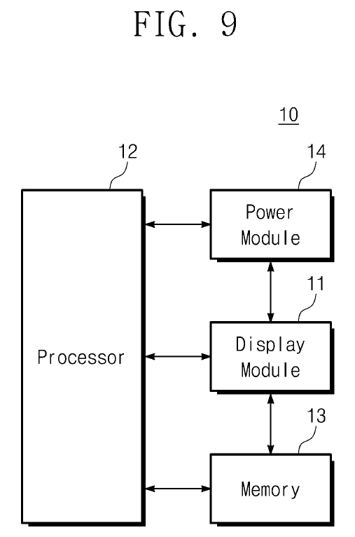

FIG. 9 is a block diagram of an electronic device (“apparatus”) according to an embodiment. Referring to FIG. 9, an electronic apparatus 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may control the operation of the display device according to an embodiment of the present inventive concept.

The memory 13 may store data information necessary for the operation of the processor 12 or the display module 11. If the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts power supplied by the power supply module to generate power required for the operation of the electronic apparatus 10.

The electronic apparatus 10 described above includes the display device according to embodiments described above, and at least one of the components of the electronic apparatus 10 may be included in the display device. In addition, some of the individual modules functionally included in one module may be included in the display device, and other parts may be provided separately from the display device. For example, the display device may include the display module 11, and the processor 12, the memory 13, and the power module 14 may be provided in the form of other devices other than the display device within the electronic apparatus 10.

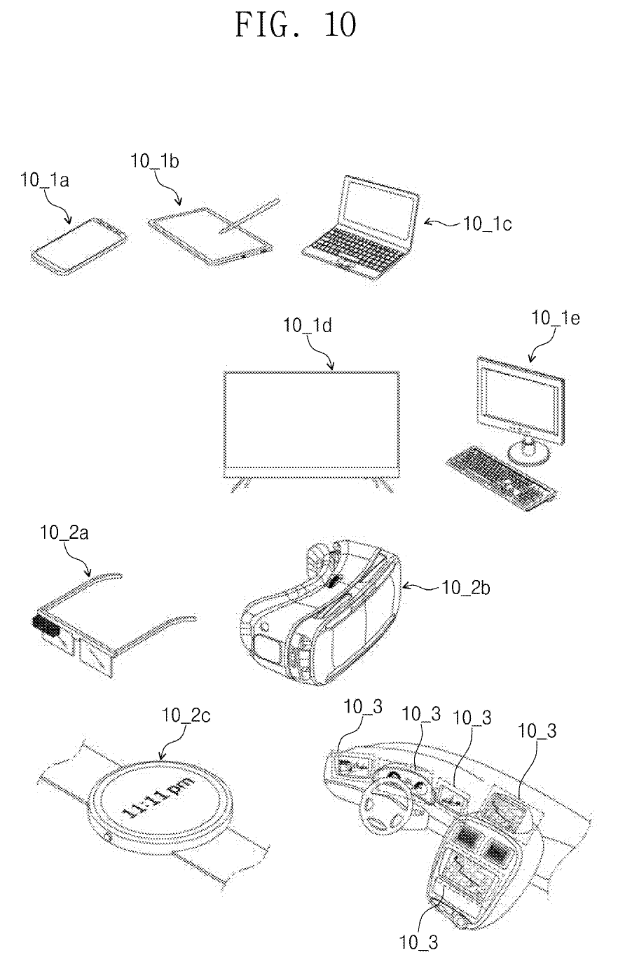

FIG. 10 illustrates schematic diagrams of electronic apparatuses according to various embodiments.

Referring to FIG. 10, various electronic apparatuses to which the display device according to embodiments is applied may include not only image display electronic apparatuses such as a smart phone 10_1a, a tablet PC 10_1b, a laptop 10_1c, a TV 10_1d, and a desk monitor 10_1e, but also wearable electronic apparatuses including a display module such as smart glasses 10_2a, a head-mounted display 10_2b, and a smart watch 10_2c, and vehicle electronic apparatuses 10_3 including a display module such as a dashboard of an automobile, center fascia, a center information display (CID) placed on a dashboard, and a room mirror display.

According to an embodiment of the present inventive concept, each pixel may include sub-pixels. The sub-pixels may be connected to voltage lines and data lines extending in a first direction. Here, the data lines may be disposed between the sub-pixels (e.g., in a plan view, such as in the first direction DR1), and the voltage lines may be disposed on the outside of the sub-pixels (e.g., in the plan view, such as in the first direction DR1 and a direction opposite to the first direction DR1) so that the data lines and the voltage lines are not adjacent to each other. Accordingly, the interaction between the data lines and the voltage lines may be reduced, thereby providing a display device with increased display quality.

Although the present invention has been described above with reference to non-limiting embodiments thereof, it will be understood that those skilled in the art or having ordinary knowledge in the art can modify and change the present inventive concepts in various ways without departing from the spirit and technical scope of the present inventive concepts.

Therefore, the technical scope of the present invention should not be limited to the contents described in the detailed description of the specification, but should be determined by the claims.

What is claimed is:

1. A display device comprising:
a display panel comprising a plurality of pixels, each of the plurality of pixels comprising a light emitting element and a pixel circuit connected to the light emitting element, a plurality of data lines connected to the plurality of pixels, and a plurality of voltage lines connected to the plurality of pixels;
a data driver connected to the plurality of data lines; and
a voltage generator providing a plurality of voltages to the plurality of voltage lines,
wherein the plurality of pixels comprises a first pixel and a second pixel, each of the first pixel and the second pixel comprising a first sub-pixel, a second sub-pixel, and a third sub-pixel, sequentially arranged in a first direction,
the plurality of data lines comprises a first data line connected to the first sub-pixel, a second data line connected to the second sub-pixel, and a third data line connected to the third sub-pixel,
the first data line, the second data line, and the third data line are disposed between the first sub-pixel and the third sub-pixel in a plan view, and
the plurality of voltage lines is spaced apart from the first data line, the second data line, and the third data line with the first sub-pixel or the third sub-pixel interposed therebetween in the plan view.

2. The display device of claim 1, wherein:
the first data line is disposed between the first sub-pixel and the second sub-pixel in the plan view; and
the second data line and the third data line are disposed between the second sub-pixel and the third sub-pixel in the plan view.

3. The display device of claim 2, wherein the third sub-pixel is symmetrically arranged with respect to the second sub-pixel based on the second data line and the third data line.

4. The display device of claim 1,
wherein the first and second data lines are disposed between the first sub-pixel and the second sub-pixel in the plan view; and
the third data line is disposed between the second sub-pixel and the third sub-pixel in the plan view.

5. The display device of claim 4, wherein the first sub-pixel is symmetrically arranged with respect to the second sub-pixel based on the first data line and the second data line.

6. The display device of claim 1, wherein the plurality of data lines and the plurality of voltage lines are disposed on a same layer as each other.

7. The display device of claim 1, wherein:
the display panel further comprises a plurality of horizontal voltage lines and a light shielding pattern;
the plurality of horizontal voltage lines and the light shielding pattern are disposed on a same layer as each other; and
the plurality of voltage lines is respectively connected to the plurality of horizontal voltage lines.

8. The display device of claim 1, wherein the display panel further comprises:
an insulating pattern partially covering a semiconductor pattern, and disposed under a gate; and
a first insulating layer that covers the semiconductor pattern and the gate.

9. The display device of claim 8, wherein the plurality of data lines and the plurality of voltage lines are disposed on the first insulating layer.

10. The display device of claim 1, wherein:
the plurality of voltage lines comprises a first driving voltage line, a second driving voltage line, a reference voltage line, and an initialization voltage line;
the second driving voltage line, the initialization voltage line, and the reference voltage line are spaced apart from the first data line with the first sub-pixel interposed therebetween in the plan view; and
the first driving voltage line is spaced apart from the third data line with the third sub-pixel interposed therebetween in the plan view.

11. The display device of claim 10,
wherein the pixel circuit comprises a plurality of transistors, each of the plurality of transistors comprising a semiconductor pattern and a gate; and
each of the plurality of transistors comprises:
a first transistor connected between the first driving voltage line and the light emitting element;
a second transistor connected between one of the plurality of data lines and the first transistor; and
a third transistor connected to the reference voltage line.

12. The display device of claim 11, wherein the semiconductor pattern of the first transistor is connected to a light shielding pattern overlapping the semiconductor pattern of the first transistor.

13. The display device of claim 12,
wherein the pixel circuit further comprises:
a first capacitor formed by the light shielding pattern and the gate of the first transistor; and
a second capacitor formed by the light shielding pattern and a capacitor electrode, and
the capacitor electrode is disposed on a same layer as the semiconductor pattern of the first transistor.

14. The display device of claim 13, wherein the pixel circuit further comprises:
a fourth transistor connected between the initialization voltage line and the light emitting element;
a fifth transistor connected between the first driving voltage line and the first transistor; and
a sixth transistor connected between the first transistor and the second driving voltage line.

15. The display device of claim 13, wherein the reference voltage line comprises:
a first reference voltage line connected to the third transistor; and
a second reference voltage line connected to the second capacitor.

16. The display device of claim 15, wherein:
the first pixel and the second pixel are disposed repeatedly in the first direction; and
the first pixel and the second pixel are disposed alternately in a second direction intersecting the first direction.

17. The display device of claim 16, wherein:
the first driving voltage line and the second driving voltage line are disposed between the first pixel and the second pixel in the plan view;
the first reference voltage line is adjacent to the first pixel in the plan view; and
the second reference voltage line is disposed between the first pixel and the second pixel in the plan view.

18. An electronic device comprising:
a display device; and
a processor controlling operation of the display device,
wherein the display device comprises:
a display panel comprising a plurality of pixels, each of the plurality of pixels comprising a light emitting element and a pixel circuit connected to the light emitting element, a plurality of data lines connected to the plurality of pixels, and a plurality of voltage lines connected to the plurality of pixels;
a data driver connected to the plurality of data lines; and
a voltage generator providing a plurality of voltages to the plurality of voltage lines,
wherein the plurality of pixels comprises a first pixel and a second pixel, each of the first pixel and the second pixel comprising a first sub-pixel, a second sub-pixel, and a third sub-pixel, sequentially arranged in a first direction,
the plurality of data lines comprises a first data line connected to the first sub-pixel, a second data line connected to the second sub-pixel, and a third data line connected to the third sub-pixel,
the first data line, the second data line, and the third data line are disposed between the first sub-pixel and the third sub-pixel in a plan view, and
the plurality of voltage lines is spaced apart from the first data line, the second data line, and the third data line with the first sub-pixel or the third sub-pixel interposed therebetween in the plan view.

19. The electronic device of claim 18, wherein:
the first data line is disposed between the first sub-pixel and the second sub-pixel in the plan view;
the second data line and the third data line are disposed between the second sub-pixel and the third sub-pixel in the plan view; and
the third sub-pixel is symmetrically arranged with respect to the second sub-pixel based on the second data line and the third data line.

20. The electronic device of claim 18, wherein the plurality of data lines and the plurality of voltage lines are disposed on a same layer as each other.
